(19) United States
(12) Patent Application Publication
(10) Pub. No.: US 2003/0174560 A1
(43) Pub. Date: Sep. 18, 2003

(54) Photochromic compounds for molecular switches and optical memory

(76) Inventors: Klaus-Hermann Dahmen, Tallahassee, FL (US); Igor Muravyov, Tallahassee, FL (US)

Correspondence Address: Kevin W. King, SUTHERLAND ASBILL & BRENNAN LLP, 999 Peachtree Street, NE, Atlanta, GA, 30309-3996, US

(21) Appl. No.: 10/375,315

(22) Filed: Feb. 26, 2003

Related U.S. Application Data
(60) Provisional application No. 60/360,159, filed on Feb. 26, 2002.

(51) Int. Cl. G11C 29/00

(52) U.S. Cl. 365/200

(57) ABSTRACT

An organic photochromic material suitable for use as a molecular switch is provided. It comprises a substituted diarylethene that exhibits both reversible photochromic behavior and nondestructive readout is provided. In a preferred embodiment, the diarylethene comprises conjugated substituents groups that produce fluorescence in the open-ring form of the isomer, but substantially no fluorescence in the closed-ring form of the isomer. In one embodiment, the diarylethene comprises 1,2-Bis-(2-(2-benzothiazolyl)-benzo[b]thien-3-yl)perfluorocyclopentene; 1,2-Bis-(2,5-bis-(2-benzothiazolyl)-thien-3-yl)perfluorocyclopentene; or a combination thereof. The molecular switch compound is useful as memory media, for example, 3-D memory media. In one embodiment, the molecular switch compound is dispersed in a UV-transparent polymeric matrix.

### CROSS-REFERENCE TO RELATED APPLICATIONS

Priority is claimed under 35 U.S.C. § 119 to U.S. provisional application Ser. No. 60/360,159, filed Feb. 26, 2002.

### BACKGROUND OF THE INVENTION

This invention is generally in the field of materials for information storage and retrieval at the molecular level, and more particularly molecular switches, which can be useful in digital optical data systems for example.

The design of molecular switches and trigger elements offers a formidable challenge on the road toward miniaturization in future technology and the development of materials for information storage and retrieval at the molecular level. Nanoscale architectures, mechanical devices, catalysts, transport systems, sensors, surface properties of materials, and target-directed delivery systems are only a few of the myriad of applications that can be controlled using molecular switches.

The success of digital optical data systems, employing light to record information, has created a strong demand for molecular switches. Molecular switches hold the potential for use as light-based recording and storage media capable of providing high storage density and high switching rates. Consequently, the search for molecular memory elements for light-based data processing has especially gained great impetus in the past decade.

For example, optical memory storage devices such as compact disks (CD) and magneto-optical (MO) disks are becoming essential as audio and visual storage media, as well as external computer data storage media. In these devices, a laser beam is used to record and read information by applying heat to the surface of the storage media. Since the laser spot can be focused to within 1 μm, higher densities and capacities can be achieved with optical memory than with conventional magnetic memory.

However, the data density achievable by optical memory devices is ultimately limited by the diffraction of electromagnetic waves. Present data-recording techniques have nearly attained this upper limit with commercially available CD and MO disks. Even the use of an infinitely large objective lens with a high numerical-aperture (NA) value cannot reduce the bit data resolution distance for recording and reading to less than one-half the beam wavelength for conventional media.

Media formed from polymer compositions incorporating molecular switches may well provide the high storage density and high switching rates required in light-based recording and storage media. Molecular switches are generally defined as molecules that exhibit a quantifiable, reversible, change in physical properties upon exposure to a particular stimulus. Accordingly, the basic requirement for a molecular switch is bistability, i.e., the occurrence of two different forms of a molecule, which can be interconverted by means of a particular external stimulus. The bistability can be based on a variety of molecular properties, including isomerizations, electron transfer, and differences in complexation behavior. A number of different stimuli can be used to achieve the interconversion between the bistable states. Examples of these stimuli include light, heat, pressure, magnetic or electric fields, pH change, or chemical reactions.

The use of organic materials to form molecular switches offers the advantages of easy fabrication, the possibility of shaping the organic materials into the desired structures by molecular engineering, the ability to fine-tune a large variety of physical properties by changes in the molecular structure, and the ability to characterize single isolated structures to allow the study of fundamental problems.

Photoreversible compounds are especially attractive organic materials for use as molecular switches. Photoreversible compounds are stimulated by light, i.e., they provide reversible switching processes based on photochemically induced interconversions. Photochromism, a reversible change induced by light irradiation between two states of a molecule having different electromagnetic absorption spectra, is commonly associated with such photoreversible systems. The photochromic switching processes are typically based on photocyclization of isomers, the conversion of (cis-trans) isomers, photoinduced electron transfer, and keto-enol tautomerism.

Photochromic materials may be particularly useful in increasing the achievable density in optical memory media. More specifically, photochromic materials would allow the use of photon-mode recording, based on photochemical reactions within the medium, as opposed to the heat mode recording employed in conventional optical media. In photon-mode recording, light characteristics such as wavelength, polarization, and change can be multiplexed to enable data storage, and thus potentially dramatically increase the achievable memory density.

In addition to multiplexing, one developmental photon-mode recording technology overcomes the current memory density limit by introducing an additional axial dimension to the recording process. In this method the z, or longitudinal, axis is utilized in addition to the surface dimension (x-y space) utilized in conventional optical memory. Data is thus written not on the media surface, but within the three-dimensional volume of the material.

FIG. 1 provides a schematic of such a process. In general, the memory media would generally be comprised of a suitable quantity of the molecular switch compound embedded within a polymeric matrix or suspended within a solution. The polymeric matrix or solution must be selected to be transparent to the energy used to impart and decode the information contained within the molecular switches. The molecular switches within the thickness of the media could subsequently be activated using dual lasers, which converge on a given molecular switch. In such an embodiment, the wavelengths emitted by each of the lasers would combine within the molecular switch to trigger the photochemical reaction.

Since the data-recording mechanism is based on the photochemical reaction of each molecule in the matrix, extremely high spatial resolution should be achievable. For such three dimensional recording, a large two-photon absorption coefficient is preferred, because three dimensional memory essentially uses a two-photon process. Stated differently, a photon emitted by each of the two lasers X and Y in FIG. 1 combines within a particular molecule within the depth of the volumetric medium. Photochromic materials are further promising as recording media for optical memory because such data is erasably, or rewritably, stored. FIG. 2 generally illustrates the interconversion behavior of photoreversible compounds. In FIG. 2, A and B represent the two different forms of a bistable system, whereby λ₁ and λ₂ refer to the different irradiation wavelengths used to effect the reversible switching behavior between forms A and B. Referring again to FIG. 1, λ₁ or λ₂ (dependent upon the desired switch position) represents the sum of the energies E, of wavelengths λₓ and λ_{y} emitted by lasers X and Y, respectively. The sum of the energies may be determined using Equation 1:

$$E = \frac{h}{{λ}_{x}} + \frac{h}{{λ}_{y}}$$

wherein

E=the sum of the energies provided by wavelengths λₓ and λ_{y};

λₓ=wavelength emitted by laser X;

λ_{y}=wavelength emitted by laser Y; and

h=Plank's constant, 6.63×10⁻²³ (J)(s).

In addition to photochemical bistability, suitable photochromic candidates must also possess a number of additional qualities to be acceptable for use as molecular switches or trigger elements. The most important qualities include fatigue resistance, thermal stability, detectability, and nondestructive read out. Fatigue resistance is important because the organic material must be able to undergo numerous write/erase cycles without inducing thermal or photochemical degradation. Sufficient thermal stability over a large temperature range (e.g., between −20 and 80° C.) is required to prevent thermal interconversion of the organic material. Both forms of the photochromic compound should be readily detectable using conventional optical spectroscopy techniques. Of course, the detection method should not interfere with or erase the stored information.

Additional properties considered beneficial in photochromic materials intended for use as molecular switches include fast response times, high quantum yields of interconversion, and retention of the photochemical properties when the photochromic compound is incorporated into the recording media. For example, the organic photochromic compound may be embedded within a polymeric composition, as illustrated in FIG. 1. In other embodiments, it may be organized on a surface or incorporated into a multicomponent assembly.

Among various photochromic compounds, diarylethenes, particularly diarylethenes containing heterocyclic aryl groups, have been investigated as possible materials for use in optical storage media. Diarylethenes function as molecular switches via the photocyclization of its isomers, as shown in FIG. 3, which illustrates the general formula for isomers of a diarylethene containing a heterocyclic group.

Generally such compounds are substituted diarylethenes, i.e., compounds of FIG. 3 in which R is selected from the group consisting of —H, —OCH₃, —CH₃, —CH(CH₃)₂, and —(CH₂)₃CH₃; and X₁ and X₂ are independently selected from the group consisting of CH═CH, O, S, Se, and NR₇. In alternative embodiments, R₃ and R₄, together with the carbon atom to which they are attached can be cycloalkyl, and each of R₁ to R₇ can be substituted with one or more non-interfering substituents, such as, but not limited to C1-C10 alkyl, C1-C10 alkoxy, halide, and the like. Specific examples of such compounds include, but are not limited to, thienylperfluorocyclopentenes, shown as 2o (opened form) and 2c (closed form) in FIG. 4.

FIG. 5 shows the typical absorption spectral changes of these diarylethene derivatives 2o and 2c in inert solvent. In general, the open-ring isomers of the diarylethenes 2o have absorption bands λ₁ at shorter wavelengths. The open ring structure 2o absorbs light at wavelength λ₁, thereby converting the compound to the closed ring isomer 2c. The closed ring isomer, 2c, subsequently cycles back to the open ring form, 2o, upon exposure to light at longer wavelength λ₂. Most diarylethenes show large spectral shifts upon photoisomerization from the open- to the closed-ring isomers (>6500 cm⁻¹). In the closed-ring isomers 2c, π-electrons delocalize throughout the two condensed dihydro thiophene rings (that were former thiophenes) and further extend to the substituents. The absorption spectra of the open-ring isomers 2o depend on the substituents of the thiophene rings.

To date, organic photochromic materials have not been considered viable candidates due both to the range of properties required and their insufficient reliability in general. While heterocyclic diarylethenes have been developed which provide a number of properties considered beneficial in opto-electronic devices, none of the diarylethenes developed to date have provided nondestructive readout, which is indispensable in practical applications. In this regard, generally, detection processes impinge one or more wavelengths of light energy onto a target and measure the target's ability to absorb and emit the various wavelengths of light. When the various wavelengths used in the detection process do not influence the ratio of the two isomers, the readout method becomes nondestructive. However, for known compounds, destructive readout typically occurs, i.e., the signal used to determine the isomeric form of the molecule, e.g. to provide a readout, also causes the molecular switch to close. It therefore would be desirable to provide a photochromic material capable of nondestructive readout that exhibits both reversible photochromic behavior and nondestructive readout.

### SUMMARY OF THE INVENTION

An organic photochromic material comprising a substituted diarylethene that exhibits both reversible photochromic behavior and nondestructive readout is provided. In a preferred embodiment, the diarylethene comprises conjugated substituents groups that produce fluorescence in the open-ring form of the isomer, but substantially no fluorescence in the closed-ring form of the isomer.

In one embodiment, the diarylethene substituents groups comprise aromatic rings, heteroaromatic rings, alkenes, alkynes, or heteroatoms possessing an electron pair. For example, the diarylethene substituents groups may comprise benzene, naphthalene, anthracene, or phenanthrene. In one embodiment, the diarylethene substituents groups comprise a heteroaromatic group selected from furan, pyrrole, thiophene, thiazole, isothiazole, oxazole, isoxazole, pyrazole, imidazole, oxadiazoles, thiadiazoles, triazoles, tetrazoles, pyridines, diazines, triazines, tetrazines, and a condensed system containing one of these heterocycles. In a preferred embodiment, the diarylethene substituents groups comprise a benzothiazole ring. In another embodiment, the diarylethene substituents groups comprise a condensed benzene ring.

In one embodiment, the diarylethene, further comprises a non-conjugated substituent group that does not interfere with the absorption properties of the diarylethene molecule. For example, the non-conjugated substituent group could be fluorine.

In one preferred embodiment, the diarylethene comprises 1,2-Bis-(2-(2-benzothiazolyl)-benzo[b]thien-3-yl)perfluorocyclopentene. In another preferred embodiment, the diarylethene comprises 1,2-Bis-(2,5-bis-(2-benzothiazolyl)-thien-3-yl)perfluorocyclopentene.

In one embodiment, the photochromic material comprises a diarylethene compound, which forms a closed ring isomer in response to incident laser light at a wavelength λ₁ between 280 and 450 nanometers. In addition, the diarylethene compound forms an open ring isomer in response to incident laser light at a wavelength λ₂ between 500 and 800 nanometers. In one variation, in response to incident laser light at a wavelength λ₃ between 300 and 500 nanometers, the open-ring isomer fluoresces at wavelengths λ₄ between 320 and 540 nanometers. Preferably, the closed-ring isomer of this compound does not substantially absorb light at either wavelengths λ₃ or λ₄.

In one embodiment, the diarylethene compound has the following general formula and isomeric forms upon photocyclization:

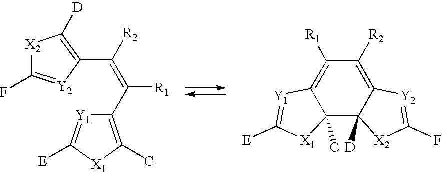

wherein

C, D, E, and F are each independently selected from the group consisting of aromatic rings, heteroaromatic rings, alkenes, alkynes, and heteroatoms possessing an electron pair;

X₁ and X₂ are each independently selected from the group consisting of CH═CH, O, S, Se, and NR₃;

R₃ is an alkyl selected from the group consisting of —CH₃, —C₂H₅, —C₃H₇, —C₄H₉, —C₅H₁₁, —C₆H₁₃, —C₇H₁₅, —C₈H₁₇, —C₉H₁₉, and —C₁₀H₂₁, or a fluorinated alkyl selected from the group consisting of —CF₃, —C₂F₅, —C₃F₇, —C₄F₉, —C₅F₁₁, —C₆F₁₃, —C₇F₁₅, —C₈F₁₇, —C₉F₁₉, —C₁₀F₂₁, —CH₂CF₃, —CH₂C₂F₅, —CH₂C₃F₇, —CH₂C₄F₉, —CH₂C₅F₁₁, —CH₂C₆F₁₃, —CH₂C₇F₁₅, —CH₂C₈F₁₇, —CH₂C₉F₁₉, and —CH₂C₁₀F₂₁;

Y₁ and Y₂ are each independently selected from N and C-R₄; and

R₄ is selected from the group consisting of H, R₃ alkyls, R₃ fluorinated alkyls, aromatic rings, heteroaromatic rings, alkenes, alkynes, and heteroatoms possessing an electron pair.

In another aspect, a memory medium is provided. Preferably, the medium comprises a polymeric base material; and a plurality of molecular switches integrated into or onto the polymeric base material, wherein the molecular switches comprise an organic photochromic material capable of nondestructive readout comprising a substituted diarylethene that exhibits both reversible photochromic behavior and nondestructive readout. In one embodiment, the molecular switches are dispersed in a polymeric matrix comprising the polymeric base material, for example, for implementation into a 3-D memory device. In another embodiment, the molecular switches are coated onto a surface of the polymeric base material. In one variation of this, layers of base material could be stacked alternately with layers of molecular switches.

In one embodiment, the polymeric base material is transparent to ultraviolet light. The polymeric base material may comprise, for example, a polyolefin or a polycarbonate. In one embodiment, the polymeric base material (and the memory medium) is in the shape of a disk. In one aspect, an optical storage device is provided which comprises the memory medium.

In yet another aspect, a method of switching a molecular switch in a memory medium is provided. For example, the method steps preferably include (1) providing a memory medium which comprises a molecular switch comprising a substituted diarylethene that exhibits both reversible photochromic behavior and nondestructive readout; and (2) applying electromagnetic irradiation energy to the molecular switch at a first wavelength effective to cause an open ring isomer of the diarylethene to form a closed ring isomer, applying electromagnetic irradiation energy to the molecular switch at a second wavelength effective to cause a closed ring isomer of the diarylethene to form a open ring isomer, or a combination thereof. The source of the electromagnetic irradiation energy preferably comprises a laser.

### BRIEF DESCRIPTION OF THE FIGURES

FIG. 1 is a schematic illustrating a 3-D memory media comprising molecular switches embedded throughout a polymeric matrix, and operable using a two-laser system for reading and writing to the media.

FIG. 2 is an illustration of the interconversion behavior of photoreversible compounds.

FIG. 3 is an illustration of the general formula for isomers of a diarylethene containing a heterocyclic group, showing how the diarylethenes function as molecular switches via the photocyclization of its isomers.

FIG. 4 is an illustration of the structure of thienylperfluorocyclopentene, shown in an open form isomer (2o) and in a closed form isomer (2c).

FIG. 5 is a graph showing typical absorption spectral changes of thienylperfluorocyclopentene 2o and 2c in inert solvent.

FIG. 6 is a schematic illustration of various irradiation processes involved in the recordation and detection of a molecular switch, having open-ring isomer A, closed-ring isomer B, and excited state A*.

FIG. 7 is an illustration of the general formula for isomers of a substituted diarylethene that exhibits both reversible photochromic behavior and nondestructive readout, wherein the diarylethene comprises conjugated substituents groups that produce fluorescence in the open-ring form of the isomer, but substantially no fluorescence in the closed-ring form of the isomer.

FIG. 8 is an illustration of the structural formula for 1,2-Bis-(2-(2-benzothiazolyl)-benzo[b]thien-3-yl)perfluorocyclopentene, in its photoreversible open (4o) and closed (4c) isomeric forms.

FIG. 9 is an illustration of the structural formula for 1,2-Bis-(2,5-bis-(2-benzothiazolyl)-thien-3-yl)perfluorocyclopentene, in its photoreversible open (5o) and closed (5c) isomeric forms.

FIG. 10 is an illustration of a reaction scheme for making 1,2-Bis-(2-(2-benzothiazolyl)-benzo[b]thien-3-yl)perfluorocyclopentene (4o), from 2-benzothiazol-2-yl-3-bromobenzo[b]thiophene (I) and octafluorocyclopentene.

FIG. 11 is an illustration of a reaction scheme for making 1,2-Bis-(2,5-bis-(2-benzothiazolyl)-thien-3-yl)perfluorocyclopentene (5o), from 2,5-bis-(2-benzothiazolyl)-3-bromothiophene (II) and octafluorocyclopentene.

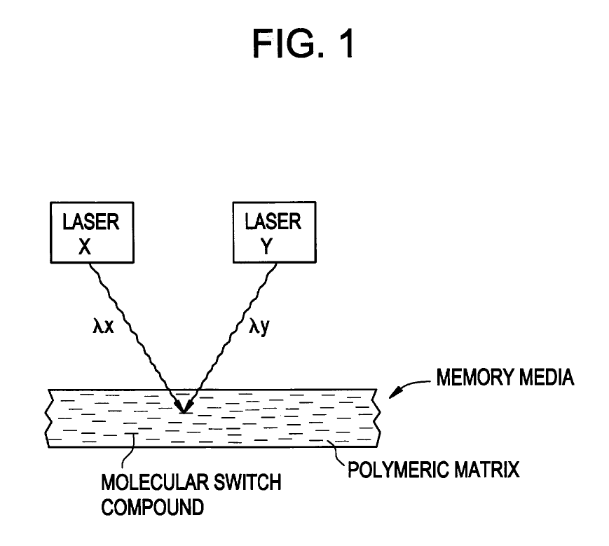

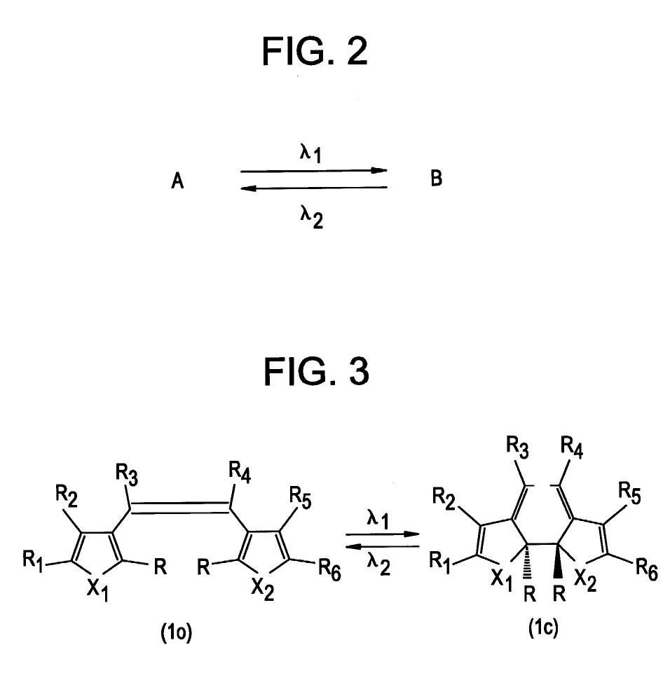

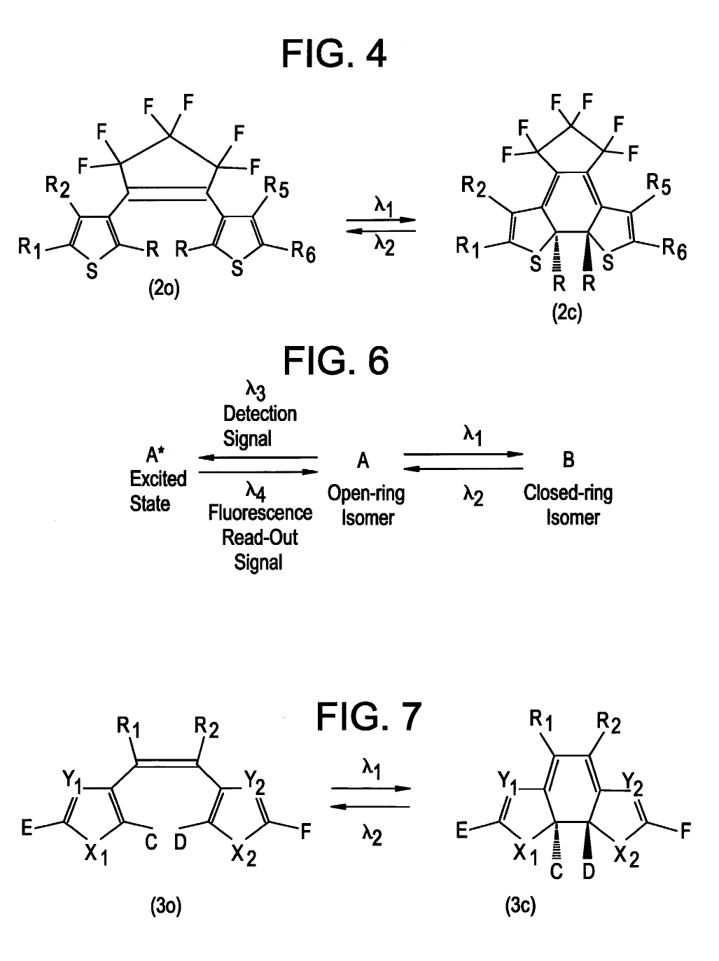

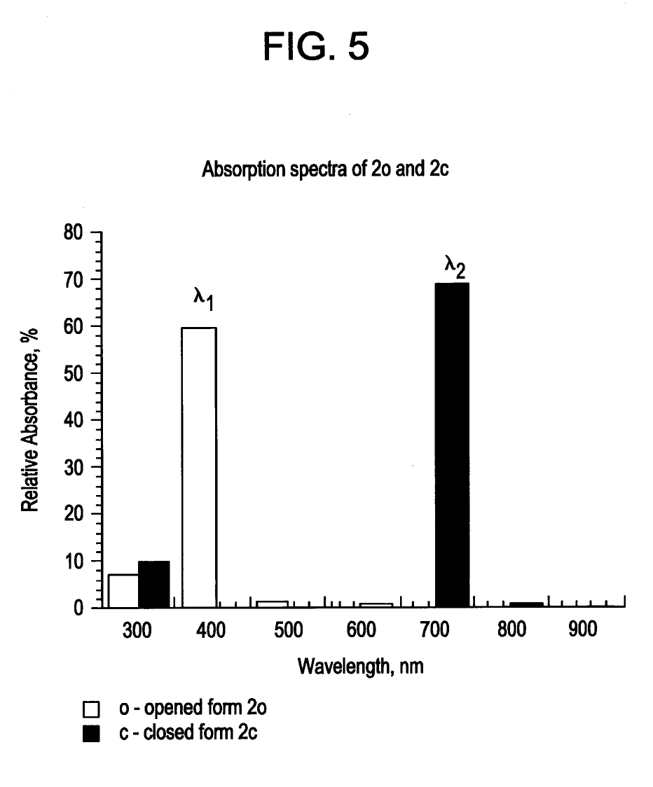

### DETAILED DESCRIPTION OF THE INVENTION

Organic photochromic compounds have been developed, with which both switching and non-destructive detection may be accomplished using electromagnetic irradiation energy. These compounds are therefore highly useful as molecular switches.

The Photochromic Compounds

It has been determined that by providing increased conjugation within diarylethene molecules as a whole, the wavelengths at which cyclization and fluorescence are induced become more defined. More particularly, it has been have found that the addition of suitable highly conjugated substituent groups onto diarylethene molecules leads to the presence of fluorescence in the open-ring form of the isomer, with no, or minimal, fluorescence in the closed-ring form of the isomer.

In a preferred embodiment, the organic photochromic compounds are defined by the structure in FIG. 7. The fluorescent quenching behavior of the diarylethenes is generally observed when an effective amount of conjugation is present between the aryl unit and its substituents in the opened-ring form 3o, and when at least a portion of the conjugation within the molecule is subsequently destroyed in closed-ring from 3c, thereby “switching off” the fluorescent properties upon photocyclization. Open-ring isomer conjugation generally arises when each of the substituent groups at positions C, D, E and F in FIG. 7 are sufficiently conjugated, i.e., each possesses at least two double bonds alternating with at least one single bond. The conjugation within the substituent groups must further conjugate with at least one double bond within the aryl group of the core structure 3o to which it is bonded. Upon cyclization, the single bond arising between the two aryl groups destroys the conjugation path between the substituent groups C and D and the two aryl groups, thereby quenching fluorescence.

Consequently, the substituent groups C through F may be any moieties capable of providing sufficient conjugation to give rise to fluorescence in the open-ring isomer. Exemplary substituent groups C through F may be independently selected from the group consisting of aromatic rings, heteroaromatic rings, alkenes, alkynes and heteroatoms possessing an electron pair. Suitable aromatic groups include without limitation benzene, naphthalene, anthracene, phenanthrene; as well as heteroaromatic groups such as furan, pyrrole, thiophene, thiazole, isothiazole, oxazole, isoxazole, pyrazole, imidazole, all oxadiazoles, all thiadiazoles, all triazoles, tetrazoles, pyridines, all diazines, all triazines, all tetrazines, all possible condensed systems containing the aforementioned heterocycles, and the like. In one particularly advantageous embodiment, the heteroaromatic ring is a benzothiazole ring. In an alternative advantageous embodiment, the aromatic rings are condensed benzene rings. Generally, any known fluorophoric group that does not interfere with the opening and closing of the molecular structure may be suitably employed as a substituent group.

X₁ and X₂ as well as Y₁ and Y₂ may be any moiety capable of forming a conjugated aryl structure. For example, X₁ and X₂ may independently be selected from the group consisting of CH═CH, O, S, Se, and NR₃. R₃ may be an alkyl group, such as —CH₃, —C₂H₅, —C₃H₇, —C₄H₉, —C₅H₁₁, —C₆H₁₃, —C₇H₁₅, —C₈H₁₇; —C₉H₁₉; —C₁₀H₂₁, as well as fluorinated analogs thereof, such as —CF₃, —C₂F₅, —C₃F₇, C₄F₁₉, —C₅F₁₁, —C₆F₁₃, —C₇F₁₅, —C₈F₁₇, —C₉F₁₉, —C₁₀F₂₁, or alternatively, —CH₂CF₃, —CH₂C₂F₅, —CH₂C₃F₇, —CH₂C₄F₉, —CH₂C₅F₁₁, —CH₂C₆F₁₃, —CH₂C₇F₁₅, —CH₂C₈F₁₇, —CH₂C₉F₁₉, —CH₂C₁₀F₂₁, and the like.

The fragments represented as Y₁ and Y₂ may independently be selected from N or C-R₄, where R₄ can be H, R₃, or any groups described as suitable for E and F. Y₁ and Y₂ in conjunction with E and F may form condensed or bridged systems, as specified for substituents C through F.

The moieties comprising R₁ and R₂ may be any suitable group or compound providing stiffness to the molecule without interfering with its absorption properties. In advantageous embodiments, the combination of R₁ and R₂ provide a fluorine-containing, bridge-forming five-member carbocycle. Fluorine has been found to be particularly beneficial, because it enhances the solubility of the compound and does not provide reactive sites to interfere with the photo reaction. Perfluorinated cyclic structures further impart rigidness to the resulting molecule. The provision of a suitable degree of rigidness within the diarylethene compounds is believed to be advantageous, because it provides physical stability to the molecule during the switching process, prevents possible cis-trans isomerisation along the double bond, and thus facilitates the opening and closing process.

In one particularly advantageous embodiment, the heteroatomic ring is a benzothiazole ring. In another embodiment, the aromatic rings are condensed benzene rings. Again, any known fluorophoric group that does not interfere with the opening and closing of the molecular structure may be suitably employed as a substituent group. Suitable aryl groups generally include any aryl group capable of forming a conjugated structure, including heterocyclic aryl moieties.

The diarylethenes may further include non-conjugated substituent groups that do not interfere with the absorption properties of the resulting molecule. Such non-conjugated substituent groups further beneficially provide stiffness to the molecule. In one advantageous embodiment, fluorine is employed in the non-conjugated substituent group.

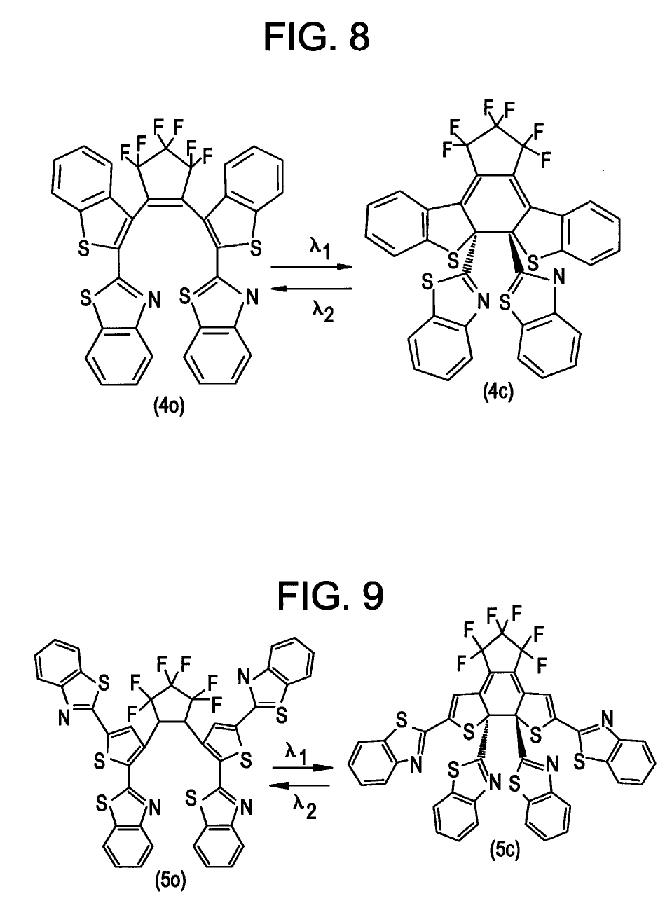

Two exemplary photochromic compounds possessing the beneficial switchable fluorescent properties are 1,2-Bis-(2-(2-benzothiazolyl)-benzo[b]thien-3-yl)perfluorocyclopentene (4o) and 1,2-Bis-(2,5-bis-(2-benzothiazolyl)-thien-3-yl)perfluorocyclopentene (5o). These are illustrated in FIG. 8 and FIG. 9, respectively.

Methods of Using the Molecular Switches

The select application of electromagnetic irradiation energy to the photochromic compounds can be used to transform a compound from an open isomeric form to a closed isomeric form or vice versa. In this way, the compounds can be used as a molecular switch, with the electromagnetic irradiation energy serving as a switching means.

The highly conjugated substituent groups on the present diarylethene molecules provides fluorescence in the open-ring form of the isomer, with no, or minimal, fluorescence in the closed-ring form of the isomer. This feature is advantageous because readout methods based on fluorescence are especially attractive due to their simplicity. Fluorescence generally arises when some of the light wavelengths impinging a target are shifted down into the longer wavelength spectrum upon their emission. Conventional optical spectroscopy methods employing fluorescence as the detection method may be used in conjunction with the presently described fluorescent photochromic materials by sampling within the material's absorption bands and recording the resulting fluorescence intensities. In advantageous embodiments, three dimensional (3-D) fluorescence spectroscopy may be applied.

FIG. 6 schematically illustrates various irradiation processes involved in the recordation and detection of molecular switches. As shown in FIG. 6, light at wavelength λ₁ is absorbed by the open-ring isomer A, thereby converting it to the closed-ring isomer B. The closed-ring isomer B may then be reconverted to its open ring isomer, A, by absorbing radiation at wavelength λ₂. In response to a detection signal at wavelength λ₃, the open-ring isomer A absorbs a portion of the energy to produce an excited state, A*, and emit energy at wavelength λ₄.

The present photochromic compounds can provide a large fluorescence intensity change between the open and closed ring isomers. The compounds are thus suitable for use as molecular switches, as this intensity change makes it possible to see the absorption shift as a readout signal from A* of λ₄. Advantageously, in fact, the open ring isomer fluoresces and the closed-ring isomer does not.

Referring again to FIG. 6, the present photochromic compounds generally respond to wavelengths λ₁ ranging from 280 to 450 nanometers (nm) to convert the open-ring isomer A to the closed-ring isomer B. An exemplary range of wavelengths λ₂ from 500 to 800 nanometers causes the closed-ring isomer B to convert back to the open-ring isomer A. The photochromic compounds have absorption bands at λ₃ of the open-ring isomer A which are substantially photochemically inactive, i.e. does not cause it to close, and causes only fluorescence of the open-ring isomer A at a wavelength, λ₄. Moreover, the closed-ring isomer does not substantially absorb the light at either the wavelength λ₃ or the emitted wavelength λ₄, so that fluorescence is an ideal readout method for the described photochemical systems. Exemplary wavelength ranges for λ₃ and λ₄ include 300 to 500 nanometers and 320 to 540 nanometers, respectively. The skilled artisan will appreciate that the photochromic materials described herein need not be limited to those responsive to the exemplary wavelength ranges described herein.

In addition to providing both switching and non-destructive detection using light energy, the present photochromic compounds can also exhibit other advantageous properties for use in optical switches, such as thermal irreversibility. In addition, the compounds can exhibit fatigue resistance, such that the ring closure/opening cycle can be repeated for up to more than 10⁴ times. Both thermal irreversibility and fatigue resistance can be indispensable for use in various applications, including opto-electronic devices, such as molecular switches.

In one embodiment, UV-Vis spectroscopy coupled with a fluorescence technique is used both to detect the percentages of open-ring and closed-ring isomers within a given quantity of diarylethene compound and to effect a shift in the isomer population. To quantify the population of isomers within a sample, light at a wavelength λ₃, is impinged upon the sample, causing compounds 4o and 5o to fluoresce, with emission of light at wavelength λ₄, which serves as a read out signal. However, the closed ring structures 4c and 5c are unaffected by λ₃, i.e. they neither fluoresce nor cycle in response to λ₃.

Different wavelengths λ₁ and λ₂ are also used to effect a shift in the isomer population, as discussed above. Excitation of the opened-ring form 4o and 5o with light at wavelength λ₁ causes predominate photocyclization leading to the closed-ring form 4c and 5c, respectively. The closed-ring isomers 4c and 5c have no significant fluorescence and predominately convert back to their respective open-ring isomers 4o and 5o in the photoreaction brought about by impinging them with light at wavelength λ₂. Such photochemical behavior is highly beneficial in organic compounds intended for use into optical media providing rewritable storage with nondestructive readout based on fluorescence detection, as discussed above. It has been found that the photochromic compounds with longer conjugation paths provide improved separation between the cyclization wavelength, λ₁, and the absorption wavelength, λ₃ that causes emission of light at λ₄.

The photochromic compounds generally form closed ring isomers in response to wavelengths λ₁ ranging from 280 to 450 nanometers. Open ring isomers are generally formed in response to wavelengths λ₂ ranging from 500 to 800 nanometers. Further, in response to light at wavelengths λ₃, ranging from 300 to 500 nanometers, the open-ring isomer fluoresces at wavelengths λ₄, ranging from 320 to 540 nanometers. The closed-ring isomer λ₃ does not absorb, or only minimally absorbs, light at either wavelengths λ₃ or λ₄, however.

Memory Media Comprising Molecular Switches

In one aspect, the photochromic compounds are incorporated into memory media, e.g., an optical storage device. One skilled in the art can readily provide a device to encode such memory (storage) media and subsequently read the encoded information.

In one embodiment, a memory medium is provided which comprises a polymeric base material and a plurality of molecular switches which comprise an organic photochromic material comprising a substituted diarylethene that exhibits both reversible photochromic behavior and nondestructive readout. In one embodiment, the molecular switches can be dispersed in a volume of a polymeric matrix comprising the polymeric base material or in a polymeric solution comprising the polymeric base material. This would be useful in 3-D memory media. In another embodiment, the molecular switches are coated onto a surface of the polymeric base material. There could be single layer of molecular switches, or alternating layers of base material and switches could be stacked to form another type of “3-D” memory media.

The amount of molecular switches that can be incorporated into the polymeric base material can vary, depending for example upon the design of the storage device, the electromagnetic irradiation energy means, and the means of measuring florescence. Exemplary loadings range between about 0.01 and about 100 wt % (e.g., between about 0.1 and 50 wt %), based on the total weight of the polymeric composition.

Suitable polymeric base materials are known in the art. In one embodiment, the polymeric base material comprises a polyolefin or a cyclo-polyolefin. In another embodiment, the polymeric base material comprises a polycarbonate.

The polymeric base material preferably is selected to be transparent to the energy used to impart and decode the information contained within the molecular switches. In a preferred embodiment, the polymeric base material is transparent to ultraviolet light. Exemplary polymers for use in a UV-transparent polymeric base material include polyolefins, such as polyethylene and polypropylene, their fluorinated analogs, and the like.

The polymeric base material containing the molecular switch material can be formed into essential any shape suitable for use in or with an optical memory device, using essentially any means known in the art, including but not limited to injection molding, extrusion, micromolding, and the like. In one embodiment, the polymeric base material is in the shape of a disk, e.g., a diskette.

The present compositions and methods are further illustrated by the following non-limiting examples.

### EXAMPLE 1

### Preparation of Molecular Switch Material 1,2-Bis-(2-(2-benzothiazolyi)-benzo[b]thien-3-yl)perfluorocyclopentene

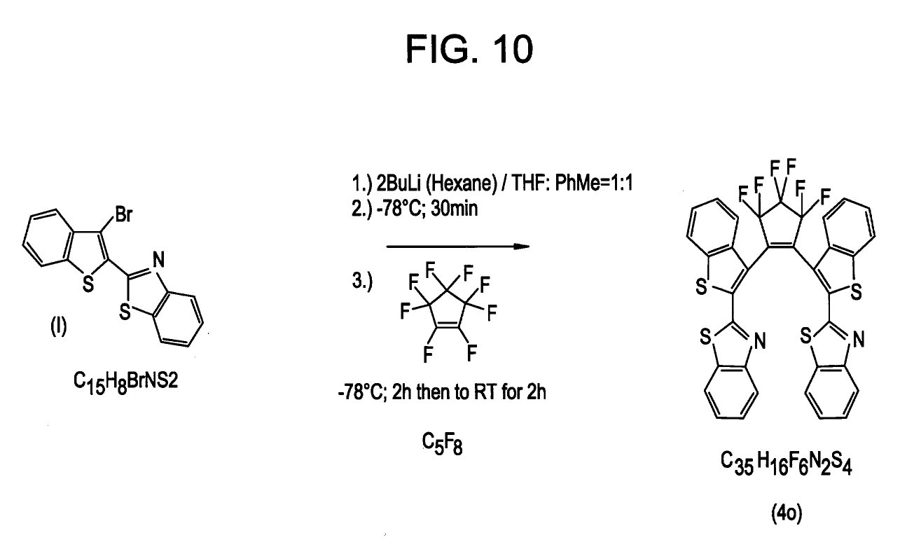

A sample of 1,2-Bis-(2-(2-benzothiazolyl)-benzo[b]thien-3-yl)perfluorocyclopentene (4o) was prepared. The reaction scheme used to make the 4o is illustrated in FIG. 10 and described below.

Initially, 0.519 g (1.5 mmol) of 2-benzothiazol-2-yl-3-bromobenzo[b]thiophene (I) was dissolved under an argon atmosphere in 40 mL of 1:1 mixture of THF and toluene (both dried with Na/ benzophenone and freshly distilled in an argon stream). The dissolved 2-benzothiazol-2-yl-3-bromobenzo[b]thiophene was subsequently cooled to −78° C. (internal temperature) with an acetone/dry ice bath. Approximately 1 mL (1.55 mmol) of 1.56M n-butyllithium was then added to the cooled 2-benzothiazol-2-yl-3-bromobenzo[b]thiophene over a 10 minute period, and the mixture was stirred for additional 30 min. at −78° C. Approximately 0.159 g (0.75 mmol) of octafluorocyclopentene in 2 mL of dry THF was then added to the 2-benzothiazol-2-yl-3-bromobenzo[b]thiophene mixture through a rubber septum using a syringe. After the addition of the octafluorocyclopentene, the solution was stirred at −78° C. for approximately 2 hours, after which the cooling bath was removed. The solution was then allowed to warm to room temperature under continual stirring for another 2 hr, forming a darkened greenish-colored solution. Approximately 2 mL of methanol was then added to the mixture and the solvents were evaporated. Approximately 50 mL of 1N HCl was added following evaporation. The resulting mass was extracted with 5×50 mL of CHCl₃. The combined organic phases were dried over MgSO₄ and evaporated, yielding a brown semisolid substance. This crude product was chromatographed on silica gel (230-60 mesh) using benzene as an eluent, yielding 0.278 g (52% yield) of 4o as an off-white solid.

### EXAMPLE 2

### Preparation of Molecular Switch Material

1,2-Bis-(2,5-bis-(2-benzothiazolyl)-thien3-yl)perfluorocyclopentene

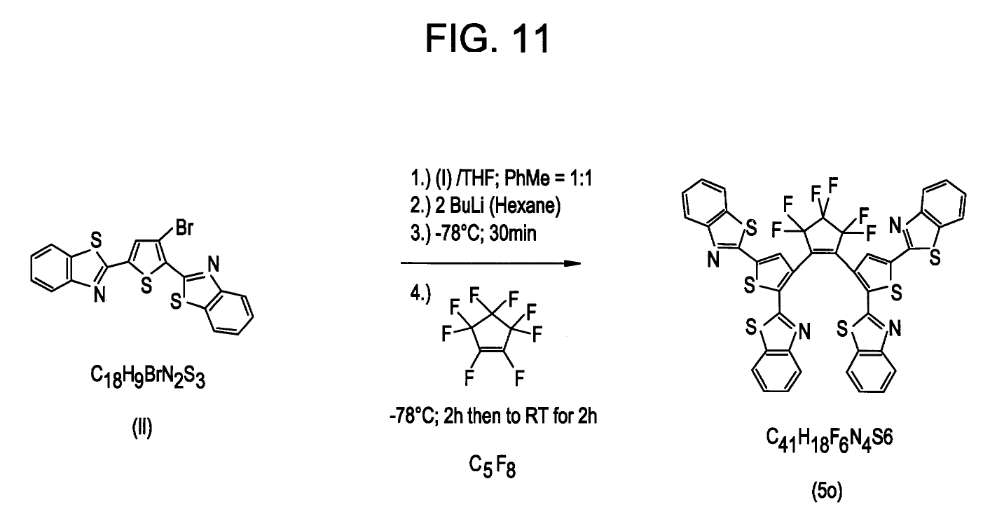

A sample of 1,2-Bis-(2,5-bis-(2-benzothiazolyl)-thien-3-yl)perfluorocyclopentene (5o) was prepared. The reaction scheme used to make the 5o is illustrated in FIG. 11 and described below.

Initially, 0.250 g (0.58 mmol) of 2,5-bis-(2-benzothiazolyl)-3-bromothiophene (II) was dissolved under an argon atmosphere in 50 mL of 1:1 mixture of THF and toluene (both dried with Na/ benzophenone and freshly distilled in an argon stream) and the mixture was subsequently cooled to −78° C. (internal temperature) with an acetone/dry ice bath. Approximately 0.39 mL (0.6 mmol) of 1.56 M n-butyllithium was added to the dissolved 2,5-bis-(2-benzothiazolyl)-3-bromothiophene solution over a 5 minute period. The mixture was stirred for an additional 30 min. at −78° C., and then approximately 0.062 g (0.29 mmol) of octafluorocyclopentene in 2 mL of dry THF was added through a rubber septum using a syringe. Following the addition of the octafluorocyclopentene, the solution was stirred at −78° C. for an additional 2 hours. The cooling bath was then removed, and the solution was allowed to warm to room temperature under continued stirring for another 2 hours, forming a greenish-black solution. Approximately 2 mL of methanol was then added to the room temperature solution. The solvents were removed from the mixture by evaporation, and 50 mL of 1N HCl was added. The resulting mass was extracted with 6×50 mL of CHCl₃; the combined organic phases were dried over MgSO₄ and evaporated, yielding a dark-brown semisolid. This crude product was chromatographed on silica gel (230-60 mesh) using CH₂Cl₂ as an eluent, yielding 0.046 g (18% yield) of 1,2-Bis-(2,5-bis-(2-benzothiazolyl)-thien-3-yl)perfluorocyclopentene (5o) as a fluorescent greenish-yellow solid.

The 5o product was further purified using preparative TLC with exclusion of light utilizing 1:30 mixture of ether and benzene. The TLC plate was visualized with UV light and washed off the carrier silica gel with ether. The solvent was evaporated and the procedure was repeated except for the light exclusion; the TLC plate was irradiated with 366 nm UV light upon development.

### EXAMPLE 3

### Production of a Storage Medium Comprising 4o or 5o

Storage media would be formed by incorporating molecular switch compounds 4o or 5o, made, for instance, as described in Examples 1 and 2, respectively, into a UV-transparent polymeric material. The UV-transparent polymeric material would be a polycarbonate or cyclopolyolefin. The loading of molecular switch compound 4o or 5o in the polymeric material would be between 1 and 99 wt %, based on the total weight of the polymeric composition. The molecular switch compound 4o or 5o would be uniformly dispersed throughout the polymeric material and then formed (e.g., molded) into a monolithic structure suitable for use as a memory media device, e.g., a disk.

Modifications and variations of the methods and devices described herein will be obvious to those skilled in the art from the foregoing detailed description. Such modifications and variations are intended to come within the scope of the appended claims.

We claim:

1. An organic photochromic material capable of nondestructive readout comprising a substituted diarylethene that exhibits both reversible photochromic behavior and nondestructive readout.

2. The photochromic material of claim 1, wherein the diarylethene comprises conjugated substituents groups that produce fluorescence in the open-ring form of the isomer, but substantially no fluorescence in the closed-ring form of the isomer.

3. The photochromic material of claim 2, wherein the diarylethene substituents groups comprise aromatic rings, heteroaromatic rings, alkenes, alkynes, or heteroatoms possessing an electron pair.

4. The photochromic material of claim 2, wherein the diarylethene substituents groups comprise benzene, naphthalene, anthracene, or phenanthrene.

5. The photochromic material of claim 2, wherein the diarylethene substituents groups comprise a heteroaromatic group selected from the group consisting of furan, pyrrole, thiophene, thiazole, isothiazole, oxazole, isoxazole, pyrazole, imidazole, oxadiazoles, thiadiazoles, triazoles, tetrazoles, pyridines, diazines, triazines, and tetrazines.

6. The photochromic material of claim 2, wherein the diarylethene substituents groups comprise a condensed system containing a heterocycle selected from the group consisting of furan, pyrrole, thiophene, thiazole, isothiazole, oxazole, isoxazole, pyrazole, imidazole, oxadiazoles, thiadiazoles, triazoles, tetrazoles, pyridines, diazines, triazines, and tetrazines.

7. The photochromic material of claim 2, wherein the diarylethene substituents groups comprise a benzothiazole ring.

8. The photochromic material of claim 2, wherein the diarylethene substituents groups comprise a condensed benzene ring.

9. The photochromic material of claim 2, wherein the diarylethene further comprises a non-conjugated substituent group that does not interfere with the absorption properties of the diarylethene molecule.

10. The photochromic material of claim 9, wherein the non-conjugated substituent group comprises fluorine.

11. The photochromic material of claim 1, wherein the diarylethene comprises 1,2-Bis-(2-(2-benzothiazolyl)-benzo[b]thien-3-yl)perfluorocyclopentene; 1,2-Bis-(2,5-bis-(2-benzothiazolyl)-thien-3-yl)perfluorocyclopentene; or a combination thereof.

12. The photochromic material of claim 1, wherein the diarylethene compound forms a closed ring isomer in response to incident laser light at a first wavelength λ₁ between 280 and 450 nanometers.

13. The photochromic material of claim 12, wherein the diarylethene compound forms an open ring isomer in response to incident laser light at a second wavelength λ₂ between 500 and 800 nanometers.

14. The photochromic material of claim 13, wherein in response to incident laser light at a third wavelength λ₃ between 300 and 500 nanometers, the open-ring isomer fluoresces at wavelengths λ₄ between 320 and 540 nanometers.

15. The photochromic material of claim 14, wherein the closed-ring isomer does not substantially absorb light at either wavelengths λ₃ or λ₄.

16. The photochromic material of claim 1, wherein the diarylethene compound has the following general formula and isomeric forms upon photocyclization: 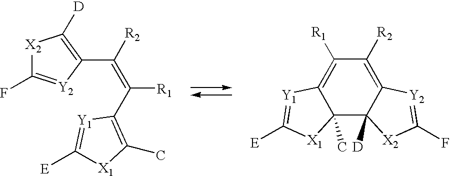
wherein
C, D, E, and F are each independently selected from the group consisting of aromatic rings, heteroaromatic rings, alkenes, alkynes, and heteroatoms possessing an electron pair;
X₁ and X₂ are each independently selected from the group consisting of CH═CH, O, S, Se, and NR₃;
R₃ is an alkyl selected from the group consisting of —CH₃, —C₂H₅, —C₃H₇, —C₄H₉, C₅H₁₁, —C₆H₁₃, —C₇H₁₅, —C₈H₁₇, —C₉H₁₉, and —C₁₀H₂₁, or a fluorinated alkyl selected from the group consisting of —CF₃, —C₂F₅, —C₃F₇, —C₄F₉, —C₅F₁₁, —C₆F₁₃, —C₇F₁₅, —C₈F₁₇, —C₉F₁₉, —C₁₀F₂₁, —CH₂CF₃, —CH₂C₂F₅, —CH₂C₃F₇, —CH₂C₄F₉, —CH₂C₅F₁₁, —CH₂C₆F₁₃, —CH₂C₇F₁₅, —CH₂C₈F₁₇, —CH₂C₉F₁₉, and —CH₂C₁₀F₂₁;
Y₁ and Y₂ are each independently selected from N and C-R₄; and
R₄ is selected from the group consisting of H, R₃ alkyls, R₃ fluorinated alkyls, aromatic rings, heteroaromatic rings, alkenes, alkynes, and heteroatoms possessing an electron pair.

17. The photochromic material of claim 16, wherein C, D, E, and F are each independently selected from the group consisting of benzene, naphthalene, anthracene, and phenanthrene.

18. The photochromic material of claim 16, wherein C, D, E, and F each independently comprise a heteroaromatic group selected from the group consisting of furan, pyrrole, thiophene, thiazole, isothiazole, oxazole, isoxazole, pyrazole, imidazole, oxadiazoles, thiadiazoles, triazoles, tetrazoles, pyridines, diazines, triazines, and tetrazines.

19. The photochromic material of claim 16, wherein C, D, E, and F each independently comprise a condensed system containing a heterocycle selected from the group consisting of furan, pyrrole, thiophene, thiazole, isothiazole, oxazole, isoxazole, pyrazole, imidazole, oxadiazoles, thiadiazoles, triazoles, tetrazoles, pyridines, diazines, triazines, and tetrazines.

20. The photochromic material of claim 16, wherein C, D, E, and F each independently comprise a benzothiazole ring.

21. A memory medium comprising:
a polymeric base material; and
a plurality of molecular switches integrated into or onto the polymeric base material, wherein the molecular switches comprise an organic photochromic material comprising a substituted diarylethene that exhibits both reversible photochromic behavior and nondestructive readout.

22. The memory medium of claim 21, wherein the diarylethene comprises conjugated substituents groups that produce fluorescence in the open-ring form of the isomer, but substantially no fluorescence in the closed-ring form of the isomer.

23. The memory medium of claim 22, wherein the diarylethene substituents groups comprise aromatic rings, heteroaromatic rings, alkenes, alkynes, or heteroatoms possessing an electron pair.

24. The memory medium of claim 22, wherein the diarylethene substituents groups comprise benzene, naphthalene, anthracene, or phenanthrene.

25. The memory medium of claim 22, wherein the diarylethene substituents groups comprise a heteroaromatic group selected from the group consisting of furan, pyrrole, thiophene, thiazole, isothiazole, oxazole, isoxazole, pyrazole, imidazole, oxadiazoles, thiadiazoles, triazoles, tetrazoles, pyridines, diazines, triazines, and tetrazines.

26. The memory medium of claim 22, wherein the diarylethene substituents groups comprise a condensed system containing a heterocycle selected from the group consisting of furan, pyrrole, thiophene, thiazole, isothiazole, oxazole, isoxazole, pyrazole, imidazole, oxadiazoles, thiadiazoles, triazoles, tetrazoles, pyridines, diazines, triazines, and tetrazines.

27. The memory medium of claim 22, wherein the diarylethene substituents groups comprise a benzothiazole ring.

28. The memory medium of claim 22, wherein the diarylethene substituents groups comprise a condensed benzene ring.

29. The memory medium of claim 22, wherein the diarylethene further comprises a non-conjugated substituent group that does not interfere with the absorption properties of the diarylethene molecule.

30. The memory medium of claim 29, wherein the non-conjugated substituent group comprises fluorine.

31. The memory medium of claim 21, wherein the diarylethene comprises 1,2-Bis-(2-(2-benzothiazolyl)-benzo[b]thien-3-yl)perfluorocyclopentene; 1,2-Bis-(2,5-bis-(2-benzothiazolyl)-thien-3-yl)perfluorocyclopentene; or a combination thereof.

32. The memory medium of claim 21, wherein the diarylethene compound has the following general formula and isomeric forms upon photocyclization: 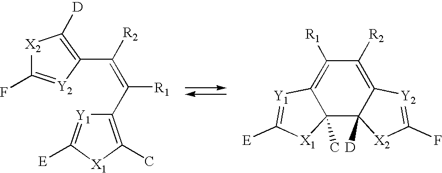
wherein
C, D, E, and F are each independently selected from the group consisting of aromatic rings, heteroaromatic rings, alkenes, alkynes, and heteroatoms possessing an electron pair;
X₁ and X₂ are each independently selected from the group consisting of CH═CH, O, S, Se, and NR₃;
R₃ is an alkyl selected from the group consisting of —CH₃, —C₂H₅, —C₃H₇, —C₄H₉, —C₅H₁₁, C₆H₁₃, —C₇H₁₅, —C₈H₁₇, —C₉H₁₉, and —C₁₀H₂₁, or a fluorinated alkyl selected from the group consisting of —CF₃, —C₂F₅, —C₃F₇, —C₄F₉, —C₅F₁₁, —C₆F₁₃, —C₇F₁₅, —C₈F₁₇, —C₉F₁₉, —C₁₀F₂₁, —CH₂CF₃, —CH₂C₂F₅, —CH₂C₃F₇, —CH₂C₄F₉, —CH₂C₅F₁₁, —CH₂C₆F₁₃, —CH₂C₇F₁₅, —CH₂C₈F₁₇, —CH₂C₉F₁₉, and —CH₂C₁₀F₂₁;
Y₁ and Y₂ are each independently selected from N and C-R₄; and
R₄ is selected from the group consisting of H, R₃ alkyls, R₃ fluorinated alkyls, aromatic rings, heteroaromatic rings, alkenes, alkynes, and heteroatoms possessing an electron pair.

33. The memory medium of claim 21, wherein the molecular switches are dispersed in a polymeric matrix comprising the polymeric base material.

34. The memory medium of claim 21, wherein the molecular switches are coated onto a surface of the polymeric base material.

35. The memory medium of claim 21, wherein the polymeric base material is transparent to ultraviolet light.

36. The memory medium of claim 21, wherein the polymeric base material comprises a polyolefin or a polycarbonate.

37. The memory medium of claim 21, wherein the polymeric base material is in the shape of a disk.

38. An optical storage device comprising the memory medium of claim 21.

39. A method of switching a molecular switch in a memory medium comprising:
providing a memory medium which comprises a molecular switch comprising a substituted diarylethene that exhibits both reversible photochromic behavior and nondestructive readout; and
applying electromagnetic irradiation energy to the molecular switch at a first wavelength effective to cause an open ring isomer of the diarylethene to form a closed ring isomer, applying electromagnetic irradiation energy to the molecular switch at a second wavelength effective to cause a closed ring isomer of the diarylethene to form a open ring isomer, or a combination thereof.

40. The method of claim 39, wherein the electromagnetic irradiation energy is generated by a laser.

41. The method of claim 40, wherein the first wavelength λ₁ is between 280 and 450 nanometers.

42. The method of claim 40, wherein the second wavelength λ₂ is between 500 and 800 nanometers.
